(19) United States
(12) Patent Application Publication
(10) Pub. No.: US 2012/0234670 A1
(43) Pub. Date: Sep. 20, 2012

(54) MACHINE AND METHOD FOR METALLIZATION OF THREE-DIMENSIONAL OBJECTS OF SMALL SIZES

(75) Inventor: LUCIANO PEREGO, MERATE (IT)

(73) Assignee: TAPEMATIC S.P.A., ORNAGO (MB) (IT)

(21) Appl. No.: 13/093,066

(22) Filed: Apr. 25, 2011

(30) Foreign Application Priority Data
Mar. 18, 2011 (IT) MI2011A000432

(51) Int. Cl. C23C 14/14; C23C 14/34

(52) U.S. Cl. 204/192.1; 204/298.26

(57) ABSTRACT

A machine for metallization of three-dimensional objects of small sizes comprising a feeding device (2) to supply a succession of objects to be metallized (20), a metallizing device (3) comprising a main sputtering chamber (31) in a condition of permanent vacuum and a loading and unloading chamber (30) for a single object, which can be switched between a vacuum condition and an ambient-pressure condition and is operatively connected to the sputtering chamber (31), an unloading device (4) for the succession of metallized objects (21), which is operatively placed downstream of the metallizing device (3), and a painting station (10, 14) of the airless type and operatively disposed downstream of the feeding device (2) and upstream of the unloading device (4).

The present invention relates to a machine ad a method for metallization of three-dimensional objects of small sizes, such as scent bottles, stoppers or corks and the like, whose characteristic sizes are in the order of few centimetres (2-10 cm), for example.

Metallization is a surface finishing work capable of fully transforming the surface of an article of manufacture making it precious and enhancing the aspect thereof, to such a degree that a mere printed item takes a more sophisticated and precious appearance.

Metallization makes it possible to perfectly imitate other types of colours, those obtained through the galvanic bath process for example, thus enabling articles made of a “poor” material (be it plastic or metal material) to be considered aesthetically similar to more valuable articles (chromium- or gold-plated articles, for example).

In particular, the present invention refers to a metallization method using the sputtering technique. This technique is performed through ejection of atoms, ions or molecular fragments from a solid material, referred to as target, bombarded with a beam of energetic particles, generally a ion plasma. The ion plasma hits the target that, due to collision, releases atoms and particles that recondense on the surfaces of the object that is wished to be coated. The target consists of the material designed to carry out coating of the object.

This process is made in a vacuum chamber. For correct implementation of the metallization process using the sputtering technique, the article of manufacture is required to be first painted with a primer for covering possible surface faults that could impair the following metallization step.

Obviously, the primer layer must be fully dry before carrying out metallization of the article of manufacture.

The machines and methods for metallization of three-dimensional objects of small sizes of the known art contemplate the presence of a spray painting station for depositing the primer onto the articles of manufacture and a subsequent station for eliminating the solvent contained in the spray to enable drying of the primer.

Downstream of the solvent-eliminating station a metallization chamber is provided where the true metallization step is carried out.

In particular, a plurality of articles of manufacture are introduced into the metallization chamber and subsequently the vacuum is created inside the chamber to allow metallization of the articles of manufacture.

When transfer of the micrometric metal layer onto the articles of manufacture has been completed (the characteristic time for this operation being of a few seconds), the chamber is opened for extraction of the metallized articles.

These articles are sometimes further submitted to a painting process to be coated with a protective layer (or for further colouring).

In the methods and machines implementing the above described metallization methods, many articles of manufacture are required to be simultaneously introduced into the metallization chamber, in such a manner as to ensure a certain degree of efficiency and productivity of the plant.

In fact, against the few seconds required for the true sputtering process, the time necessary for creating the vacuum within the metallization chamber is of a few minutes, i.e. at least one order of magnitude higher than the sputtering time.

Taking into account the fact that the amount of energy required for depressurizing the metallization chamber is rather important, it is well apparent that the number of three-dimensional objects of small sizes to be metallized simultaneously must necessarily be high.

It results from the above that it is impossible to modulate the production of metallized three-dimensional objects of small sizes as much as one likes.

In addition, the methods and machines implementing the prior art metallization methods described above are unable to operate in a continuous manner, as they require a continuous assistance by the operators assigned to transfer of the batches of articles of manufacture between the operating stations and in addition bulky and expensive storage spaces are necessary for the articles to be treated, those partly treated but not yet metallized and those already metallized but still to be treated with a final finishing operation.

In this context, the technical task underlying the present invention is to propose a machine and a method for metallization of three-dimensional objects of small sizes overcoming the aforesaid drawbacks of the known art.

In particular, it is an aim of the present invention to propose a machine and a method for metallization of three-dimensional objects of small sizes carrying out finishing with a continuous process.

Another aim of the present invention is to propose a machine and a method for metallization of three-dimensional objects of small sizes that is fully automated.

It is a further aim of the present invention to propose a machine and a method for metallization of three-dimensional objects of small sizes offering a good production flexibility.

The technical task mentioned and the aims specified are substantially achieved by a machine and a method for metallization of three-dimensional objects of small sizes comprising the technical features set out in one or more of the appended claims.

Further features and advantages of the present invention will become more apparent from the description given by way of non-limiting example of a preferred but not exclusive embodiment of a machine and a method for metallization of three-dimensional objects of small sizes, as illustrated in the accompanying drawings, in which:

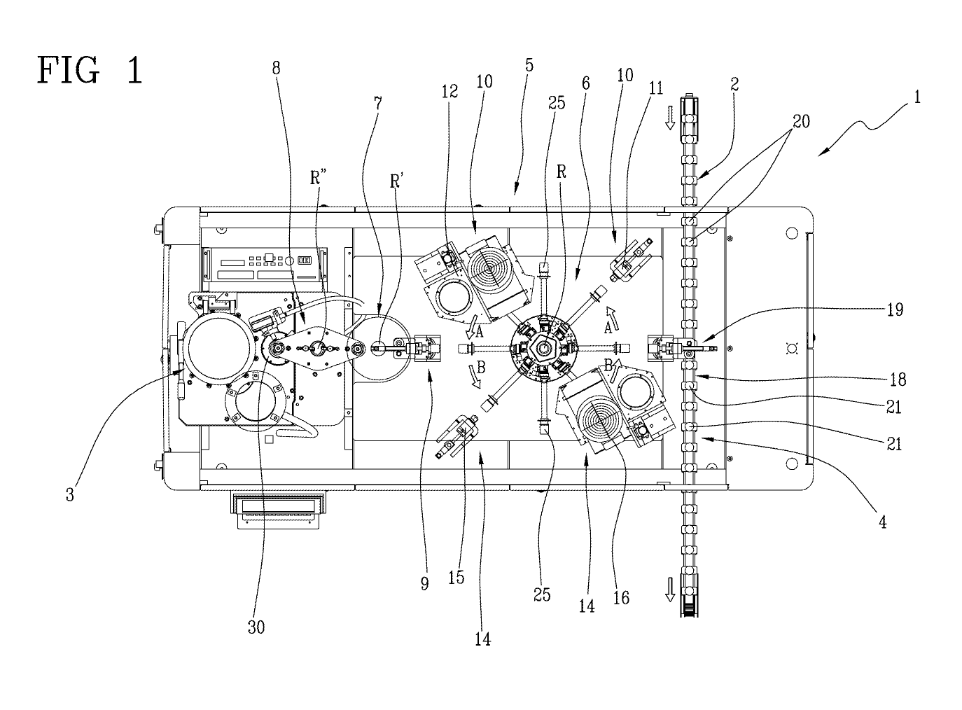

FIG. 1 is a top view of the machine according to the present invention;

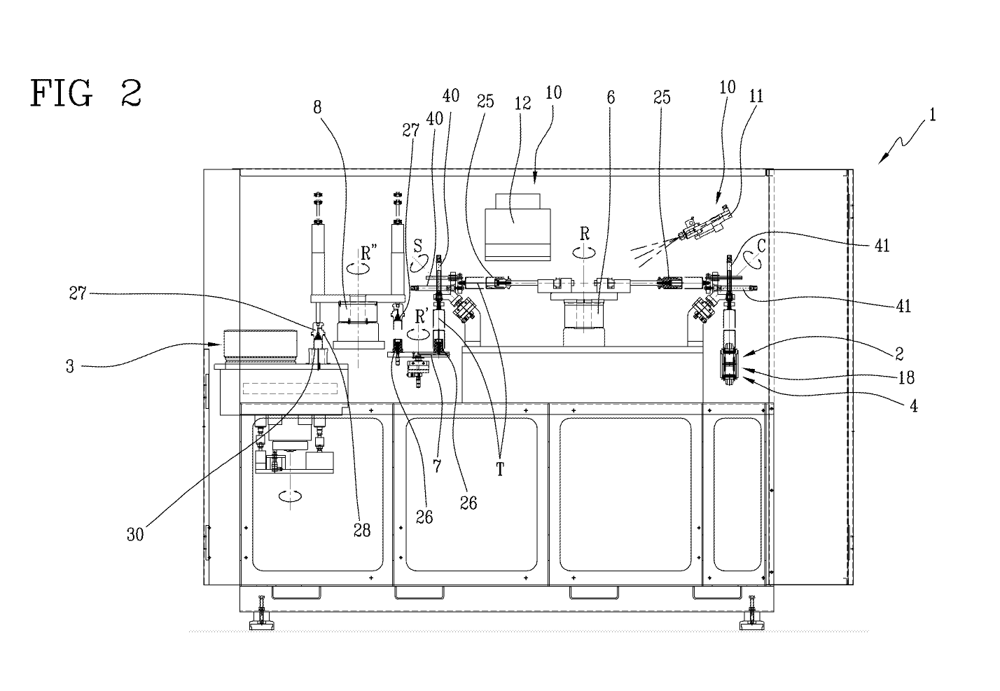

FIG. 2 is a side view of the machine seen in FIG. 1;

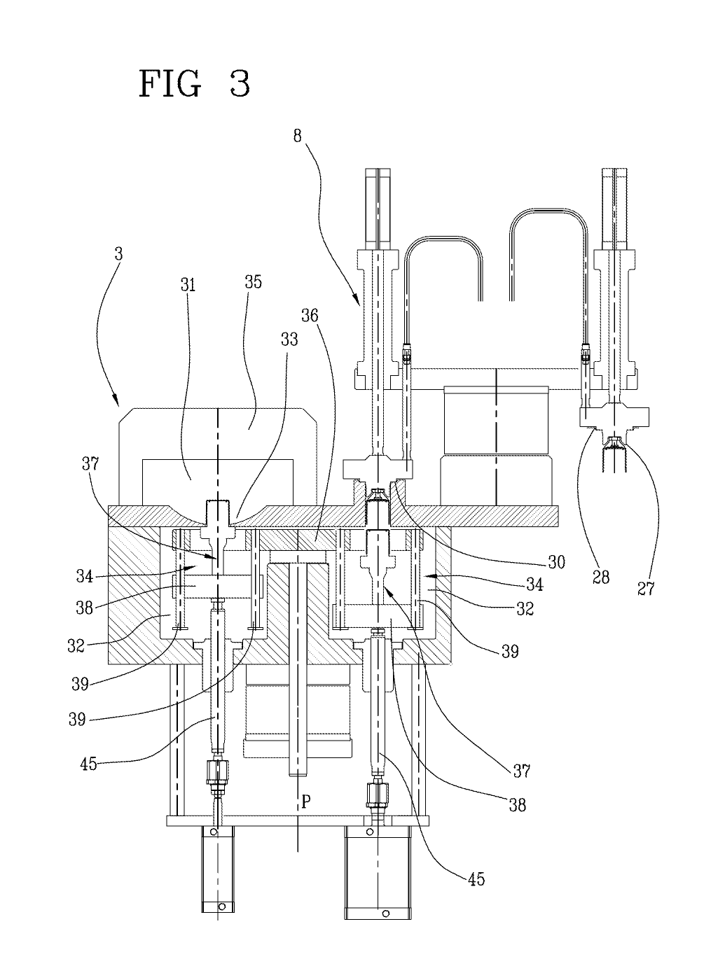

FIG. 3 is a side view in section of a detail of the machine seen in FIG. 1.

With reference to the drawings, a machine for metallization of three-dimensional objects of small sizes, such as scent bottles, stoppers and the like whose characteristic sizes are in the order of few centimetres (2-10 cm), according to the present invention has been denoted by 1.

In the following specification reference will be explicitly made to plastic stoppers or corks as an example of the above mentioned objects.

It is to be noted that the same description is valid for any other object falling within the above definition, inclusive of objects made of metal material (such as aluminium).

Referring to FIG. 1, the machine 1 comprises a feeding device 2 for providing a succession of stoppers to be metallized 20 disposed along a preferably continuous row.

The feeding device 2 comprises an actuating member 18 acting on the stoppers to be metallized 20. As shown, such an actuating member 18 is a linear conveyor and, by way of example, can be a conveyor belt.

Stoppers to be metallized 20 are picked up by an actuating device 5 moving each stopper along the machine 1.

The machine 1 further comprises a metallizing device 3 carrying out metallization of the stopper to be metallized 20 following the sputtering technique. In greater detail, the metallizing device 3 comprises a main chamber 31 maintained to a constant forced vacuum condition in which the true metallization with the sputtering technique takes place.

A prechamber 32 is disposed upstream of the main chamber 31 and it too is maintained to a constant forced vacuum condition. The prechamber 32 is in fluid connection with the main chamber 31 through a passage port 33.

The prechamber 32 is in turn connected to a loading and unloading chamber 30 which is adapted to introduce the stoppers 20 to be metallized into the prechamber 32. In other words, the loading and unloading chamber 30 allows access to the prechamber 32.

The loading and unloading chamber 30 can be switched between a vacuum condition and an ambient-pressure condition to allow controlled introduction of each stopper into the main chamber 31 (through prechamber 32). In other words, in the loading and unloading chamber 30 continuous pressurisation cycles are carried out when the loading and unloading chamber 30 is in fluid connection with the external environment, and de-pressurisation cycles when the loading and unloading chamber 30 is in fluid connection with prechamber 32 in such a manner as to prepare stopper 20 to enter the main chamber 31 as well as to prepare the just metallized stopper 21 to come out of the metallizing device 3.

Passage from the loading and unloading chamber 30 to the main chamber 31 takes place, as above said, through prechamber 32.

In this way, at each working cycle it is necessary to depressurize only the loading and unloading chamber 30 having a much lower volume than the main sputtering chamber 31 and the prechamber 32, so that the energy required at each working cycle is minimised and also minimised is the residence time of the stopper within the metallizing device 3.

The residence time of each stopper inside the metallizing device 3 is of few seconds, i.e. 2-4 seconds.

The metallizing device 3 further comprises inner actuating means 34 disposed in the prechamber 32 for transferring each stopper 20 from the loading and unloading chamber 30 to the main chamber 31 and simultaneously bringing the metallized stopper 21 back from the main chamber 31 to a region in the vicinity of the loading and unloading chamber 30.

In the described embodiment, the prechamber 32 is of a substantially toroidal shape. The metallizing device 3 comprises a holding body 35 defining the main chamber 31. The main chamber 31 is disposed on the side diametrically opposite to the loading and unloading chamber 30 relative to a symmetry axis of the prechamber 32.

The inner actuating means 34 comprises a carrousel device 36 rotating around an axis coincident with the symmetry axis of the loading and unloading chamber 32. Carrousel 36 comprises at least two grip members 37 diametrically opposite to each other for carrying each stopper 20 towards the main chamber 31 and each metallized stopper 21 towards the loading and unloading chamber 30, each on distinct paths. Each grip member 37 is movable along a respective circular trajectory.

In addition, each grip member 37 is movable along a direction parallel to the rotation axis of carrousel 36 to bring each stopper 20 from a first position in register with the loading and unloading chamber 30 and/or the passage port 33 to a distal lowered second position in which each stopper is being moved.

Each grip member 37 comprises a receiving seat mounted on a respective carriage 38 slidable along guides 39 integral with a rotating portion of carrousel 36.

Driving means 45 is associated with each carriage 38 for translating it along the direction parallel to the rotation axis of carrousel 36. By way of example, this driving means 45 is hydraulic cylinders that can be activated on the grip members 37 when the latter have to be translated along said direction parallel to the rotation axis of carrousel 36.

In a preferred embodiment of the invention shown in the drawings, the machine 1 comprises a painting station 10 placed upstream of the metallizing device 3 for treatment of stoppers 20 before metallization.

Each stopper to be metallized 20 passes through the painting station 10 applying a paint, called primer, for covering the faults of stopper 20.

The painting station 10 is placed downstream of the feeding device 2. The painting station 10 is of the airless type, i.e. of the type where paint atomisation takes place by forcing the latter to pass through a nozzle 11 of reduced sizes at a very high pressure (of about 35 bars).

Thus air is not used for atomising the paint, and said paint is put under pressure by a pump sucking the paint, pressurising it and then sending it to the nozzle that will carry out atomisation. This type of painting enables paint overspray to be greatly reduced (thus limiting any waste of paint) and an excellent covering of the object to be obtained.

The primer application time on stopper 20 is of few seconds, i.e. 2-4 seconds.

Advantageously, the paint used does not contain solvents (or at all events the solvent therein contained is a minimal fraction) and is a paint containing a photo-initiator that, submitted to electromagnetic radiation, gives rise to a chain reaction for paint crosslinking.

To this aim, downstream of the painting station 10 a UV ray dryer 12 is provided for submitting the paint to cross-linking.

The painting station 10 may comprise, in addition to the UV ray dryer 12, an infrared oven (not shown in the accompanying figures) for eliminating the small fraction of solvent possibly still present in the paint.

It should be noted that exposure of the stopper to the UV rays is in the order of a few seconds (2-4 seconds).

The painting station 10, UV ray dryer 12 and infrared oven can not be present, in particular they are present when it is necessary to apply a primer film or coat onto the object to be metallized.

In a preferred embodiment of the invention shown in the accompanying drawings, the machine 1 also comprises a painting station 14 adapted to lacquer the metallized stoppers 21 and disposed downstream of the metallizing device 3.

In this painting station 14 a layer of protective paint is placed on each already finished stopper 21 to protect the metallic layer.

The painting station 14 is of the airless type, provided with a nozzle 15 of small sizes.

The paint or lacquer used does not contain solvents (or at all events the solvent therein contained is in a minimal fraction) and is a paint containing a photo-initiator that, submitted to electromagnetic radiation, gives rise to a chain reaction for paint crosslinking.

To this aim, downstream of the painting station 14 a UV ray dryer 16 is provided for carrying out crosslinking of the paint.

Note that exposure of the stopper to the UV rays is in the order of a few seconds (2-4 seconds).

The painting station 14 may comprise, in addition to the UV ray dryer 16, an infrared oven (not shown in the accompanying drawings) for eliminating the possible small fractions of solvent still present in the paint.

Note that exposure of the stopper to the infrared rays is in the order of a few seconds (2-4 seconds).

The painting station 14, UV ray dryer 16 and infrared oven can not be present, in particular they are present when it is necessary to apply a final coating on the already metallized object.

Downstream of the painting station 14, if any, or downstream of the metallizing device 3, the metallized stoppers 21 are disposed on an unloading device 4 so as to provide a succession of metallized stoppers 21 disposed along a preferably continuous row that are conveyed out of the machine 1, preferably by the same actuating member 18 as used in the feeding device 2.

The actuating device 5 acts along each of the described operating stations to move the stoppers to be metallized 20 and the metallized stoppers 21 respectively, one at a time, in succession along the whole machine 1.

In detail, the actuating device 5 comprises a carrousel conveyor 6 operatively active between the feeding device 2 and metallizing device 3.

The carrousel conveyor 6 carries each stopper to be metallized 20, one at a time, from the feeding device 2 to the metallizing device 3 along a first path A.

In addition, the same carrousel conveyor 6 is operatively active between the metallizing device 3 and the unloading device 4 in such a manner as to carry each metallized stopper 21, one at a time, from the metallizing device 3 to the unloading device 4 along a second path B that is distinct from the first path A.

It should be noted that advantageously the step of moving stoppers 20 from the feeding device 2 to the metallizing device 3 is carried out simultaneously with the step in which stoppers 21 are transferred from the metallizing device 3 to the unloading device 4. In addition, both said steps are accomplished by the same carrousel conveyor 6.

As shown in FIG. 1, the carrousel conveyor 6 comprises a plurality of grip seats 25 spaced apart the same distance and opposite two by two relative to a rotation axis R of the carrousel conveyor 6.

During operation of the machine 1, each grip seat 25 receives a single stopper to be metallized 20 from the feeding device 2 and carries it along the first path A to the metallizing device 3. The portion of the first path defined by this grip seat 25 is in the shape of a semi-circumference.

When the stopper to be metallized 20 is delivered to the metallizing device 3, the corresponding grip seat 25 is occupied by a metallized stopper 21 coming from the metallizing device 3. Each grip seat 25 travels along the second path B towards the unloading device 4. This portion too of the second path B is in the shape of a semi-circumference.

It should be noted that while each grip seat 25 travels along the first path A, the corresponding grip seat 25 that is diametrically opposite relative to the rotation axis R travels along the second path B.

Still with reference to FIG. 1, the carrousel conveyor 6 is also active in the painting station 10 along the first path A.

Operatively interposed between the carrousel conveyor 6 and the metallizing device 3 is a transfer conveyor 7 and an overturning device 9. In greater detail, the overturning device 9 is placed between the carrousel conveyor 6 and the transfer conveyor 7.

The transfer conveyor 7 is of the rotary type and in particular it rotates around its own rotation axis R′, disposed parallel to the rotation axis R of the carrousel conveyor 6.

In the same manner as specified for the carrousel conveyor 6, the transfer conveyor 7 comprises two grip seats 26 of its own that are opposite relative to the rotation axis R′ of the transfer conveyor 7. Said grip seats 26 are simultaneously occupied by a stopper to be metallized moving towards the metallizing device 3 and a metallized stopper 21 moving towards the carrousel conveyor 6, respectively.

In other words, while one of the grip seats 26 of the transfer conveyor 7 travels along a portion of the first path A, the other grip seat 26 of the transfer conveyor 7 travels along a portion of the second path B. Both said portions of the first A and second B paths are of semi-circular shape.

The overturning device 9, placed between the carrousel conveyor 6 and the transfer conveyor 7, carries out transfer of the stoppers to be metallized 20 and the metallized stoppers 21 between said conveyors.

In fact, it should be noted that when both the stoppers to be metallized 20 and the metallized stoppers 21 are on the carrousel conveyor 6, they lie with an extension axis T thereof orthogonal to the rotation axis R of the carrousel conveyor 6 itself.

On the contrary, when both the stoppers to be metallized 20 and the metallized stoppers 21 are on the transfer conveyor 7, they lie with their extension axis T parallel to the rotation axis R′ of the transfer conveyor 7 itself.

In this connection, the overturning device 9 comprises at least two gripping arms 40 integral with each other and inclined. As shown in particular in FIG. 2, the gripping arms 40 are substantially perpendicular to each other.

The overturning device 9 can rotate along a bisecting axis S relative to the two gripping arms 40.

As shown, the bisecting axis S is substantially disposed at 45° relative to a reference vertical axis. In detail, the bisecting axis S is substantially disposed at 45° relative to the rotation axis R of the carrousel conveyor 6 or the rotation axis R′ of the transfer conveyor 7.

One of the gripping arms 40 carries the stoppers to be metallized 20 from the carrousel conveyor 6 to the transfer conveyor 7 carrying out a 180° rotation and travelling over a portion of the first path A, while simultaneously the other gripping arm 40 carries the metallized stoppers 21, one at a time, in succession from the transfer conveyor 7 to the carrousel conveyor 6 carrying out a 180° rotation and travelling over a portion of the second path B.

In addition, the actuating device 5 comprises an introduction/extraction device 8 to introduce and extract each stopper to be metallized 20 and each metallized stopper 21 respectively, into and from the metallizing device 3.

The introduction/extraction device 8 is operatively placed between the transfer conveyor 7 and the metallizing device 2. In other words, the introduction/extraction device 8 introduces a stopper to be metallized 20 into the metallization device 3 and simultaneously removes a metallized stopper 21 therefrom.

The introduction/extraction device 8 is a conveyor rotating around a rotation axis R″ thereof. The introduction/extraction device 8 comprises at least two grip seats 27 that are diametrically opposite relative to the rotation axis R″. Each grip seat 27 is respectively occupied by a stopper to be metallized 20 entering the metallizing device 3 along a stretch of the first path A and a metallized stopper 21 coming out of the metallizing device 3 along a stretch of the second path B.

Each grip seat 27 of the introduction/extraction device 8 is movable not only along circular paths, but also along a direction substantially parallel to the rotation axis R″ of said introduction/extraction device 8.

In detail, each grip seat 27 is movable between a first position that is raised relative to the loading and unloading chamber 30 of the metallizing device 3 and a second position (that is to a lower location relative to the first one) in which it is at the same height as the loading and unloading chamber 30.

In particular, the first distal position is taken up by the grip seats 27 during rotation of the introduction/extraction device 8, and therefore during travelling along the first A and second paths B.

The second position is taken up when each grip seat 27 of the introduction/extraction device 8 is in register with one of the grip seats 26 of the transfer conveyor for receiving a stopper to be metallized 20 and deliver a metallized stopper 21.

In addition, this second position is taken when each grip seat 27 of the introduction/extraction device 8 is close to the loading and unloading chamber 30 of the metallizing device 3.

Advantageously, each grip seat 27 of the introduction/extraction device 8 comprises a sealing member 28 sealing the loading and unloading chamber 30 of the metallizing device 3 when the grip seat 27 takes up its second position at the loading and unloading chamber 30.

The actuating device 5 further comprises a picking up/depositing device 19 acting at least between the feeding device 2 and the carrousel conveyor 6 to transfer each stopper to be metallized 20 exactly from the feeding device 2 to the carrousel conveyor 6.

In addition, the picking up/depositing device 19 acts between the carrousel conveyor 6 and the unloading device 4 for transferring each metallized stopper 21 from the carrousel conveyor 6 to the unloading device 4.

The picking up/depositing device 19 is quite similar to the overturning device 9.

In this regard, the picking up/depositing device 19 comprises at least two hooking arms 41 integral with each other and inclined. As illustrated in particular in FIG. 2, the hooking arms 41 are substantially perpendicular to each other.

The picking up/depositing device 19 can rotate along a bisecting axis C relative to the two hooking arms 41.

As shown, the bisecting axis C is substantially disposed at 45° relative to a reference vertical axis. In detail, the bisecting axis C is substantially disposed at 45° relative to the rotation axis R of the carrousel conveyor 6.

During operation, one of the hooking arms 41 carries the stoppers to be metallized 20 from the feeding device 2 to the carrousel conveyor 6, through a 180° rotation, while simultaneously the other hooking arm 41 carries the metallized stoppers 21 in succession, one at a time, from the carrousel conveyor 6 to the unloading device, through a 180° rotation.

In the same manner as described relative to the overturning device 9, the picking up/depositing device 19 too modifies the inclination of the stoppers during said transport steps.

The invention thus described reaches the intended purposes and achieves the previously pointed out advantages.

The machine for metallization of three-dimensional objects of small sizes is fully automated, because the combined effect of the feeding device 2, the airless painting station, the metallizing device provided with the loading and unloading chamber 30 and the unloading device 4, does not call for direct intervention of operators during the machine's ordinary working.

In addition, since the machine 1 acts on one stopper at a time in a continuous manner, a good production flexibility can be obtained, i.e. it is possible to exactly produce the amount of metallized objects required each time.

1. A machine for metallization of three-dimensional objects of small sizes, comprising:
a feeding device to supply a succession of objects to be metallized;
a metallizing device comprising a main sputtering chamber in a condition of permanent vacuum for coating each object with a predetermined metallic layer, and a loading and unloading chamber for a single object, which can be switched between a vacuum condition and an ambient-pressure condition and is operatively associated with said main chamber;
an unloading device for the succession of metalized objects, which is operatively placed downstream of the metallizing device;
a painting station of the airless type and operatively disposed downstream of the feeding device and upstream of the unloading device.

2. A machine as claimed in claim 1, characterised in that it further comprises a carrousel conveyor, operatively acting at least between the feeding device and the metallizing device for carrying each object to be metallized, one at a time, from the feeding device to the metallizing device along a first path; said carrousel conveyor being further operatively active between the metallizing device and the unloading device for carrying each metallized object, one at a time, from the metallizing device to the unloading device along a second path distinct from said first path.

3. A machine as claimed in claim 2, characterised in that it further comprises a transfer conveyor rotating and acting between said carrousel conveyor and metallizing device for carrying each object to be metallized from the carrousel conveyor to the metallizing device and carrying each metallized object from the metallizing device to the carrousel conveyor.

4. A machine as claimed in claim 2, characterised in that said carrousel conveyor comprises at least two grip seats positioned opposite to each other relative to a rotation axis of said carrousel conveyor, said seats being alternately movable along the first and the second paths for transport of an object to be metallized and a metallized object, respectively.

5. A machine as claimed in claim 4, characterised in that it further comprises an overturning device operatively interposed between the carrousel conveyor and the transfer conveyor and simultaneously acting on an object to be metallized for carrying it from said carrousel conveyor to said transfer conveyor and on a metallized object for carrying it from said transfer conveyor to said carrousel conveyor, so as to modify the orientation of each object relative to the rotation axis.

6. A machine as claimed in claim 5, characterised in that the overturning device comprises at least two gripping arms inclined to each other and rotating about a bisecting axis relative to the two gripping arms, each gripping arm being alternately active on a grip seat of said carrousel conveyor and a grip seat of said transfer conveyor.

7. A machine as claimed in claim 1, characterised in that it further comprises an introduction/extraction device for each object into and from the loading and unloading chamber of the metallizing device, having grip seats of its own that are movable along a direction substantially parallel to the rotation axis of said introduction/extraction device between a first raised position relative to the loading and unloading chamber and a second position in which they are disposed at the same height as the loading and unloading chamber.

8. A machine as claimed in claim 7, characterised in that each grip seat of said introduction/extraction device comprises a sealing member acting on the loading and unloading chamber when said grip seat takes up the second position in register with the loading and unloading chamber.

9. A machine as claimed in claim 1, characterised in that said painting station of the airless type is placed upstream of the metallizing device for laying a film of primer on the object to be metallized; a UV ray dryer being placed immediately downstream of the painting station for fixing the primer film onto the object to be metallized.

10. A machine as claimed in claim 9, wherein said painting station comprises an infrared oven for eliminating the possible solvent fraction present in the paint.

11. A machine as claimed in claim 1, characterised in that said painting station of the airless type is placed downstream of the metallization device for lacquering the metallized object; a UV ray dryer being placed immediately downstream of the painting station for fixing the lacquer onto the metallized object.

12. A machine as claimed in claim 11, wherein said painting station comprises an infrared oven for eliminating the possible solvent fraction present in the paint.

13. A method for metallization of three-dimensional objects of small sizes, comprising the steps of:
providing an orderly succession of objects to be metallized at a feeding device and feed them in a row to a metallizing device;
introducing a single object to be metallized into a loading and unloading chamber of a metallizing device;
pressurising the loading and unloading chamber and introducing the object to be metallized into a main sputtering chamber of the metallizing device;
introducing the metallized object into the loading and unloading chamber and depressurizing the same;
picking up the metallized object from the metallizing device and providing a succession of metallized object at an unloading device;
painting the objects between the feeding station and unloading station, using a painting device of the airless type.

14. A method as claimed in claim 13, further comprising the step of conveying said objects to be metallized, one at a time, in succession from said feeding device to said metallizing device along a first path, and the step of conveying said metallized objects, one at a time, in succession from said metallizing device to said unloading device along a second path distinct from the first path.

15. A method as claimed in claim 14, characterised in that the step of conveying said objects to be metallized, one at a time, in succession from said feeding device to said metallizing device is simultaneous with the step of conveying said metalized objects, one at a time, in succession from said metallizing device to said unloading device.
